(19) United States
(12) Patent Application Publication
(10) Pub. No.: US 2007/0298576 A1
(43) Pub. Date: Dec. 27, 2007

(54) Methods of forming bipolar transistors by silicide through contact and structures formed thereby

(76) Inventors: Kelin J. Kuhn, Aloha, OR (US); Bo Zheng, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/472,641

(22) Filed: Jun. 21, 2006

(51) Int. Cl. H01L 21/331

(52) U.S. Cl. 438/309

(57) ABSTRACT

Methods and associated structures of forming a microelectronic device are described. Those methods may comprise forming an opening in a masking layer, implanting an amorphizing species into a silicon region disposed within the opening, wherein the silicon region comprises a portion of an emitter of a bipolar transistor; and forming a silicide layer on the silicon region.

### BACK GROUND OF THE INVENTION

Bipolar transistor devices may utilize highly diffusive silicide materials during to form portions of conductive contacts within the bipolar transistor device. These highly diffusive silicide materials may require a pre-amorphization implant to prepare the conductive contact region for the silicidation process. In some cases, the pre-amorphization implant may cause damage to an n-p boundary junction, such as a parasitic bipolar diode region, which may be present within the bipolar transistor device.

For example, a recessed shallow trench isolation (STI) that may isolate the n-p boundary regions may comprise gaps through which the pre-amorphization implant can damage the n-p boundary junction. As a result of this damage, the bipolar transistor device may exhibit high recombination and unstable ideality factors. For example such a parasitic bipolar diode region may exist between a base contact region and an emitter contact region of a vertical bipolar transistor device.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1a-1e represent structures according to an embodiment of the present invention.

FIGS. 2a-2b represent structures according to an embodiment of the present invention.

FIG. 3 represents structures according to an embodiment of the present invention.

FIG. 4 represents a system according to an embodiment of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods and associated structures of forming a microelectronic structure, such as a bipolar transistor structure, are described. Those methods may comprise forming an opening in a dielectric layer, implanting an amorphizing species into a silicon region disposed within the opening, wherein the silicon region comprises a portion of an emitter of a bipolar transistor; and forming a silicide layer on the silicon region. In some embodiments, these methods enable the creation of adjacent un-shorted n-p regions in an n-well of a vertical pnp bipolar transistor structure. Such un-shorted n-p regions serve to minimize the n-well base resistance by maximizing the numbers of available n-well taps. In this manner, precision bipolar transistor structures may be fabricated that posses reduced gain variation, improved ideality factor, and improved base resistance.

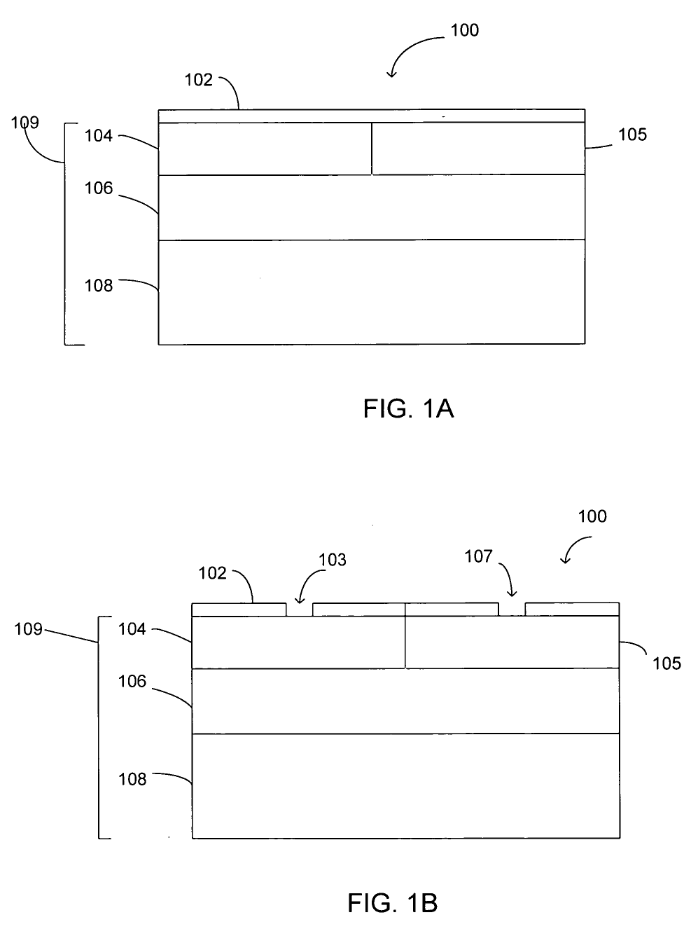

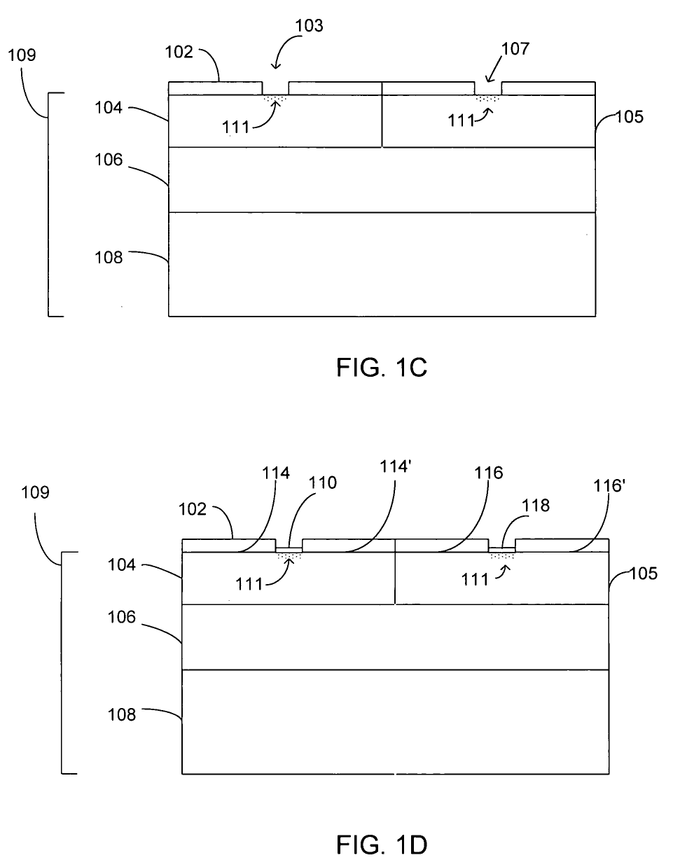

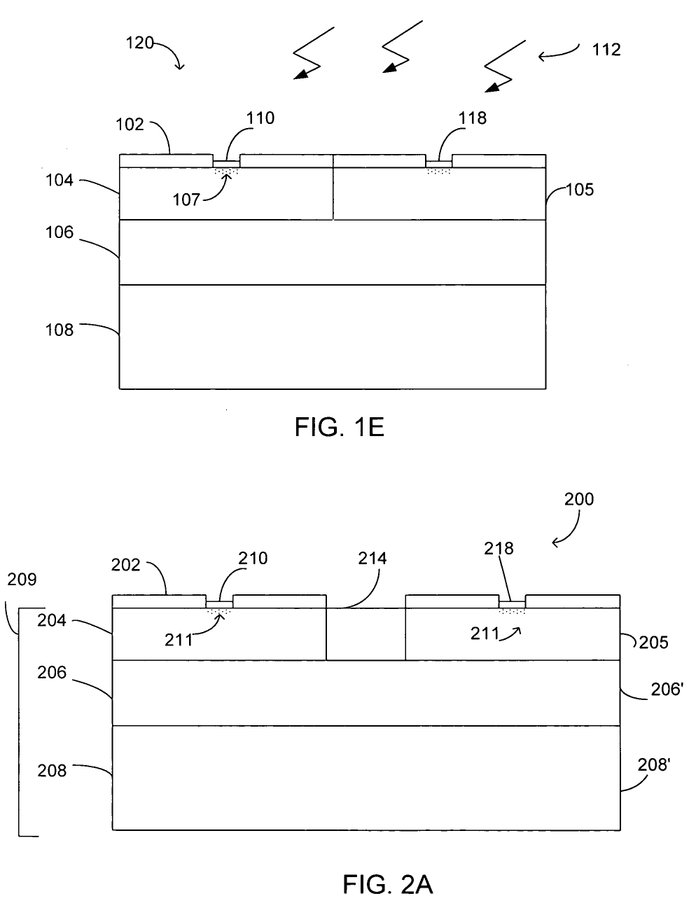

FIGS. 1a-1e illustrate an embodiment of a method and associated structures of forming a microelectronic device, such as a bipolar transistor structure, for example. FIG. 1a illustrates a cross-section of a portion of a substrate 100. In one embodiment, the substrate 100 may comprise any type of materials that may be used in the fabrication of a microelectronic device.

In one embodiment, the substrate 100 may comprise a portion of a device, such as but not limited to a vertical bipolar transistor device. In one embodiment, the substrate 100 may comprise a masking layer 102, such as a dielectric layer. In some embodiments, the masking layer 102 may comprise an interlayer dielectric material (ILD), as is known in the art. The ILD may comprise a low k ILD, in some embodiments, wherein the dielectric constant is lower than that of silicon oxide. In one embodiment, the thickness of the masking layer may range from about 0.5 microns to about 2 microns, but in general will depend upon the particular application.

The substrate 100 may comprise a silicon region 104, that may be underlying the masking layer 102. In one embodiment, the underlying silicon region 104 may comprise a p-type silicon region, and may comprise a p-type dopant, such as but not limited to boron. In one embodiment, the underlying silicon region 104 may comprise a portion of an emitter region of a vertical bipolar transistor, for example. The substrate 100 may further comprise a second silicon region 106, which in some embodiments may comprise a base region of a vertical bipolar transistor. The second silicon region 106 may be located beneath the underlying silicon region 104 that may be of an opposite conductivity type as the underlying silicon region 104. In one embodiment, the second silicon region 106 may comprise an n-type silicon region, and may comprise an n-type dopant such as arsenic, for example.

In one embodiment, the second silicon region 106 may comprise an N well area of the substrate 100, as is known in the art. The substrate 100 may also comprise a third silicon region 108, that may be of the same conductivity type as the underlying silicon region 104. In one embodiment, the third silicon region 108 may comprise a p-type silicon region, for example. The third silicon region 108 may be beneath the second silicon region 106. In one embodiment, the third silicon region 108 may comprise a collector portion of a vertical bipolar transistor. Thus, the underlying silicon region 104, the second silicon region 106 and the third silicon region 108 may comprise, in some embodiments, a portion of a vertical bipolar transistor structure 109.

The substrate 100 may further comprise an adjacent silicon region 105, that may be located beneath the masking layer 102. The adjacent underlying silicon region 105 may comprise a conductivity type that is the opposite of the underlying silicon region 104. For example, if the underlying silicon region 104 comprises a p-type conductivity material, the adjacent underlying silicon region 105 may comprise an n-type conductivity material.

In one embodiment, the underlying silicon region 104 and the adjacent underlying silicon region 105 may be substantially contiguous with each other. For example, in the case where the underlying silicon region 104 comprises a p-type material, and the adjacent underlying silicon region 105 comprises an n-type material, the underlying silicon region 104 and the adjacent underlying silicon region 105 may not be substantially isolated from each other by a dielectric material. In some embodiments, the underlying silicon region 104 and the adjacent underlying silicon region 105 may form a parasitic diode region within the substrate 100.

An opening 103 may be formed in the masking layer 102 (FIG. 1b). In one embodiment, the opening 103 may comprise an emitter contact opening of a bipolar transistor, such as the portion of the vertical bipolar transistor 109, for example. Thus, in one embodiment, an emitter contact opening for the portion of the vertical bipolar transistor 109 may be formed by removing a portion of the masking layer 102, to expose a portion of an underlying p-type silicon region 104. An opening 107 may also be formed in the masking layer 102 to expose a portion of the adjacent underlying silicon region 105. In one embodiment, the exposed portion of the adjacent underlying silicon region 105 may comprise an N well tap, as is known in the art. In one embodiment, the exposed portion of the underlying silicon region 105 may comprise a base contact region.

An amorphizing species 111 may be implanted into the underlying silicon region 104 and into the adjacent underlying silicon region 105 (FIG. 1c) through the openings 103, 107 respectively. The amorphizing species 111 may comprise any species that may amorphize the underlying silicon region 104 and the adjacent underlying silicon region 105. The amorphizing of these regions may serve to prepare them for a subsequent processing step, such as a silicidation step, for example.

The amorphizing species 111 may include, by illustration and not limitation, germanium, silicon, and combinations thereof. The amorphizing species 111 may be implanted utilizing process parameters, such as dosage, angle and energy, that may be selected and optimized according to a particular application. Because the amorphizing species 111 may be implanted through the openings 102, 107, the amorphizing species 111 may be substantially confined within the area of the openings 102, 107.

In this manner, the amorphizing species 111 that is implanted into the underlying silicon region 104 and the adjacent underlying silicon region 105 may be substantially separated between the two regions, i.e. the underlying silicon region 104 and the adjacent underlying silicon region 105 may not be shorted out by the implanted amorphizing species 111. Thus, there may be little to no damage of the conductivity boundary (i.e. the n-p boundary) between these two silicon regions.

For example, bipolar transistor manufacturing processes may make use of silicides that may comprise highly diffusive metals (such as Ni, for example). Such highly diffusive metals may require careful amorphization implants prior to a silicidation process. The use of shallow trench isolation (STI) to isolate n and p regions from each other (as in the case of STI isolation between the base contact region and the emiiter contact region of a vertical bipolar transistor), may create issues in precision diodes along STI boundaries.

This may occur because recessed STI may create gaps through which the pre-amorphization implant can damage the n-p boundary junction. Such diodes may exhibit high recombination and unstable ideality factors. By implanting through the emitter contact opening, the amorphizing implant may be isolated from a critical diode edge, i.e., n-p boundary region. Alternatively, the amorphizing implant may be eliminated completely.

A silicide layer 110 may be formed and/or reacted with the underlying silicon region 104 and an adjacent silicide layer 118 may be formed and/or reacted with the adjacent underlying silicon region 105 (FIG. 1d). The silicide layer 110 and the adjacent silicide layer 118 may comprise titanium, nickel, and combinations thereof. The silicide layer 110 and the adjacent silicide layer 118 may be substantially confined within the openings 102, 107. In one embodiment, forming the silicide layer 110 on the exposed portion of the underlying silicon region 104 may form a conductive contact to an emitter region of a bipolar transistor, such as the portion of the vertical bipolar transistor 109, for example. In one embodiment, forming the adjacent silicide layer 118 on the exposed portion of the adjacent underlying silicon region 105 may form a conductive contact to a base contact region of a bipolar transistor, such as the portion of the vertical bipolar transistor 109.

Because the masking layer 102 covers substantially all of the unexposed underlying silicon region 104 and substantially all of the unexposed adjacent underlying silicon region 105, there may be at least one unsilicided region adjacent to the silicide layer 110 and adjacent silicide layer 118. For example, there may be at least one un-silicided region 114, 144′ adjacent to the silicide layer 110 that is disposed on the underlying silicon region 104, and there may be at least one adjacent un-silicided region 116,116′ adjacent to the adjacent silicide layer 118 that is disposed on the adjacent underlying silicide layer 105. In one embodiment, there may be little to no isolating material, such as STI, that may separate the unsilicided region 114′ from the adjacent unsilicided region 116.

Traditional suicides may cover the wafer in metal and then use an anneal to form the silicide. A trench oxide, such as STI, may be used to isolate adjacent n-p regions so that silicides do not short between the regions. For example, adjacent n-p regions which do not limit the silicide material to within the opening of the amorphizing implant may create shorts between the n-p regions. By substantially confining the formation of the silicide layer 110 to the exposed portions of the underlying silicon region 104 and the exposed portions of the adjacent underlying silicon region 105, the silicide layer 110 will not short adjacent n-p junctions.

In this manner, an isolating dielectric material, such as a STI, may not be necessary to isolate n-p boundaries from each other. In one embodiment, performing the amorphizing implant through the emitter contact opening, and then forming the silicide within the emitter contact opening (and within the base contact opening) may permit adjacent n-p junctions within a vertical bipolar transistor structure, for example. The ability to locate an adjacent n-p boundary inside a common nwell (without using isolating material between them, such as STI) enables the utilization of numerous N+ taps in the nwell base region, thus minimizing the base resistance of such a bipolar transistor.

In one embodiment, the silicide layer 110 may be annealed 112 (FIG. 1e). In one embodiment, the anneal may be performed for about one hour at a temperature of about 500 degrees Celsius. In general, the anneal parameters may vary depending upon the material and particular application. The anneal 112 may reduce the contact resistance of the emitter contact region.

Thus, the methods of the present invention enable the formation of a bipolar transistor structure 120, such as a vertical bipolar transistor structure. Such a bipolar transistor structure 120 can be used as a precision diode in a bandgap reference generator circuit, for example. Additionally, such a bipolar transistor structure 120 may be used as a thermal sensor, wherein the temperature of a device, such as a portion of an integrated circuit, may be measured and/or monitored. Embodiments of the present invention may also enable the utilization of such bipolar transistors to be used as voltage regulators to generate a stable voltage source for various applications.

Various embodiments of the present invention will enable the creation of precision diodes that exhibit decreased beta variation, an improved ideality factor, as well as an improved base resistance. This will enable more accurate temperature sensing and thus better control within power management environments.

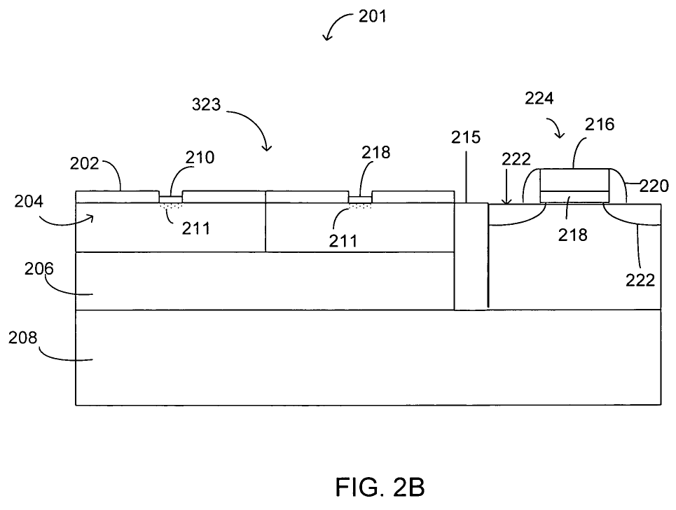

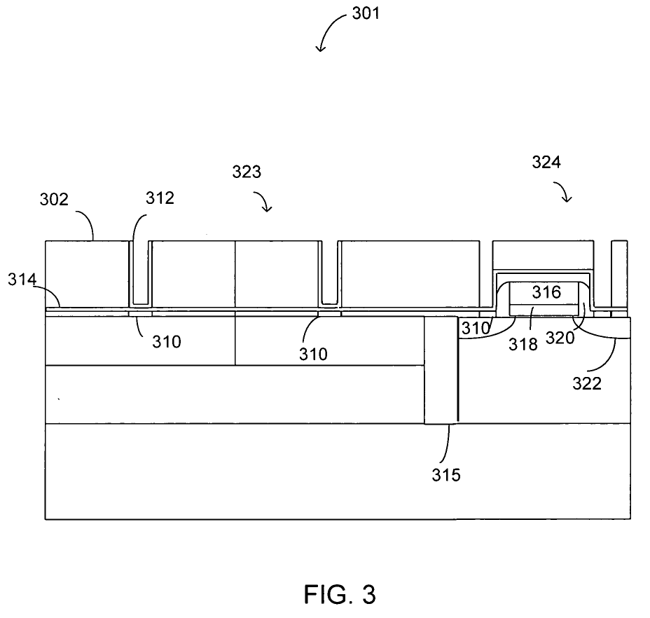

In another embodiment (see FIG. 2a), a substrate 200, (similar to the substrate 100 of FIG. 1a) may comprise a masking layer 202, a silicide layer 210, an amorphizing species 211, an underlying silicon region 204, a second silicon region 206 (that may comprise a base region) and a third silicon region 208 (that may comprise a collector region). The underlying silicon region 204, second silicon region 206 and third silicon region 208 may comprise in some embodiments portions of a vertical bipolar transistor 209.

In one embodiment, the underlying silicon region 204 may comprise an emitter region of the vertical bipolar transistor 209, and the silicide layer 210 may comprise a portion of an emitter contact to the emitter region. The vertical bipolar transistor 209 may comprise a silicide 210 that is substantially confined within the emitter contact region. The second silicon region 206 may comprise a base region of the vertical bipolar transistor 209, and the third silicon region 208 may comprise a collector region of the vertical bipolar transistor 209. A base contact silicide layer 218 may conductively contact to the base region of the vertical bipolar transistor 209.

An isolating region 214, which in some embodiments may comprise a dielectric material, and may comprise an STI, for example, may conductively isolate the underlying silicon region 204 from the adjacent silicon region 205. In this embodiment, an emitter region (underlying silicon region 204) and a base contact region (adjacent silicon region 205) of the vertical pnp bipolar transistor 209 may be additionally isolated from each other by the STI, but the benefits of confining the amorphizing implant and silicide to within the emitter contact region and base contact region may improve the ideality and reduce gain variations of a bipolar transistor manufactured according to embodiments of the present invention.

Referring to FIG. 2b, a substrate 201, which is similar to substrate 200 of FIG. 2a, but does not comprise the isolating region 214, may further include a complementary metal on silicon transistor (CMOS) portion 224, as is well known in the art. The CMOS portion 224 may include, but is not limited to, a gate oxide 218, at least one spacer region 220, a gate material 216, and at least one source/drain region 222. In some embodiments, the CMOS portion may comprise a PMOS and/or a NMOS transistor and may further comprise isolation material 215. The substrate 201 may also comprise a bipolar portion 223, in some embodiments. In one embodiment, the structure 201 may comprise a portion of a BiCMOS structure, as is well known in the art.

In another embodiment, referring to FIG. 3, a substrate 301, which is similar to the substrate 201 of FIG. 2b for example, may include the use of a CMOS ILD region 302 as a masking layer. The substrate 301 may comprise a bipolar portion 323 in some embodiments. Using the CMOS ILD region 302 in this manner allows for the simultaneous processing and/or formation of a CMOS device and a bipolar device. For example, portions of the CMOS ILD region 302 may be removed during the same process step to expose areas for the formation of both bipolar and CMOS device contacts.

Similar to FIG. 2b, a CMOS portion 324 of the substrate 301 may include, but is not limited to, a gate oxide 318, at least one spacer region 320, a gate material 316, and at least one source/drain region 322. In one embodiment, the substrate 301 may include one or more etch stop layer 314, as is known in the art. In some embodiments, a contact 310 may be formed of one or several metal layers, as are known in the art, and may incorporate one or several barrier and/or wetting layers 312. The contact 310 is illustrated in FIG. 3 as being identical on both the CMOS portion 324 and the bipolar 323 portion, but is not so required. In some embodiments, the CMOS portion 324 may comprise a PMOS and/or a NMOS transistor and may further comprise an isolation material 315. In one embodiment, the structure 301 may comprise a portion of a BiCMOS structure, as is well known in the art.

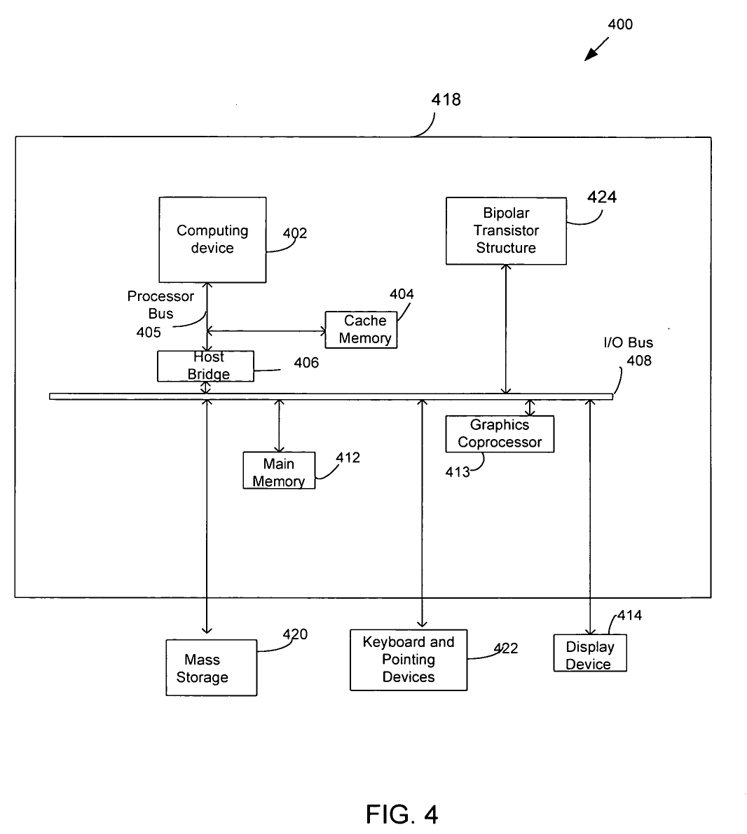

FIG. 4 is a diagram illustrating an exemplary system 400 capable of being operated with methods for fabricating a microelectronic structure, such as the bipolar transistor structure of FIG. 1e, for example. It will be understood that the present embodiment is but one of many possible systems in which the substrate core structures of the present invention may be used.

In the system 400, the bipolar transistor structure 424 may be communicatively coupled to a printed circuit board (PCB) 418 by way of an I/O bus 408. The communicative coupling of the bipolar transistor structure 424 may be established by physical means, such as through the use of a package and/or a socket connection to mount the bipolar transistor structure 424 to the PCB 418 (for example by the use of a chip package, interposer and/or a land grid array socket). The bipolar transistor structure 424 may also be communicatively coupled to the PCB 418 through various wireless means (for example, without the use of a physical connection to the PCB), as are well known in the art.

The system 400 may include a computing device 402, such as a processor, and a cache memory 404 communicatively coupled to each other through a processor bus 405. In one embodiment, the computing device 402 may comprise at least one bipolar transistor structure, similar to the bipolar transistor structure 124, for example. The processor bus 405 and the I/O bus 408 may be bridged by a host bridge 406. Communicatively coupled to the I/O bus 408 and also to the bipolar transistor structure 424 may be a main memory 412. Examples of the main memory 412 may include, but are not limited to, static random access memory (SRAM) and/or dynamic random access memory (DRAM), and/or some other state preserving mediums. In one embodiment, the main memory 412 may comprise at least one bipolar transistor structure, similar to the bipolar transistor structure 124, for example. The system 400 may also include a graphics coprocessor 413, however incorporation of the graphics coprocessor 413 into the system 400 is not necessary to the operation of the system 400. Coupled to the I/O bus 408 may also, for example, be a display device 414, a mass storage device 420, and keyboard and pointing devices 422.

These elements perform their conventional functions well known in the art. In particular, mass storage 420 may be used to provide long-term storage for the executable instructions for a method for forming and/or utilizing bipolar transistor structures in accordance with embodiments of the present invention, whereas main memory 412 may be used to store on a shorter term basis the executable instructions of a method for forming and/or utilizing bipolar transistor structures in accordance with embodiments of the present invention during execution by computing device 402. In addition, the instructions may be stored, or otherwise associated with, machine accessible mediums communicatively coupled with the system, such as compact disk read only memories (CD-ROMs), digital versatile disks (DVDs), and floppy disks, carrier waves, and/or other propagated signals, for example. In one embodiment, main memory 412 may supply the computing device 402 (which may be a processor, for example) with the executable instructions for execution.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that certain aspects of microelectronic devices, such as a FET, are well known in the art. Therefore, it is appreciated that the Figures provided herein illustrate only portions of an exemplary microelectronic device that pertains to the practice of the present invention. Thus the present invention is not limited to the structures described herein.

What is claimed is:

1. A method comprising:
forming an opening in a masking layer;
implanting an amorphizing species into a silicon region disposed within the opening, wherein the silicon region comprises a portion of an emitter of a bipolar transistor; and
forming a silicide layer on the silicon region within the opening, wherein the silicide layer is substantially confined within the opening.

2. The method of claim 1 wherein forming the silicide layer comprises forming at least one of a nickel silicide, a titanium silicide, and combinations thereof.

3. The method of claim 1 further comprising wherein the amorphizing species comprises at least one of germanium, silicon and combinations thereof.

4. The method of claim 1 wherein the bipolar transistor further comprises a collector region and a base region.

5. The method of claim 1 wherein implanting the amorphizing species comprises implanting the amorphizing species to amorphize the silicon region.

6. The method of claim 1 wherein forming the opening comprises forming an emitter contact opening.

7. The method of claim 1 wherein forming the silicide comprises forming the silicide to contact to the emitter region.

8. The method of claim 1 wherein the bipolar transistor comprises a vertical pnp bipolar transistor.

9. The method of claim 8 further comprising wherein a p-type region of the vertical pnp transistor and an adjacent n-type region do not substantially comprise an isolation region between them.

10. The method of claim 1 wherein the silicon region comprises an emitter silicon region, wherein the emitter silicon region comprises at least one unsilicided region adjacent to the silicide layer.

11. The method of claim 1 further comprising annealing the silicide layer.

12. A method comprising:
forming an emitter contact opening by removing a portion of a masking layer to expose an underlying p-type silicon region;
implanting an amorphizing species into the underlying p-type silicon region;
forming a silicide layer within the emitter contact opening on the underlying p-type silicon region to form an emitter contact region of a vertical pnp bipolar transistor.

13. The method of claim 12 further comprising wherein the vertical pnp bipolar transistor is disposed within a substrate, and wherein the substrate further comprises a CMOS transistor.

14. The method of claim 12 wherein removing a portion of a masking layer to expose an underlying p-type silicon region further comprises removing a portion of the masking layer to form at least one contact region of a CMOS transistor device.

15. The method of claim 13 further comprising wherein the p-type silicon region is substantially contiguous with an adjacent n-type silicon region.

16. The method of claim 15 further comprising wherein the p-type silicon region and the adjacent n-type silicon region are not substantially isolated from each other by a dielectric material.

17. The method of claim 12 further comprising annealing the silicide layer.

18. The method of claim 12 wherein the silicide layer is substantially confined within the emitter contact opening, and wherein the underlying p-type silicon region comprises at least one unsilicided p-type silicon region adjacent to the silicide layer.

19. A structure comprising:
an emitter contact of a vertical bipolar transistor comprising a silicide, wherein an underlying emitter silicon region comprises at least one unsilicided silicon region adjacent to the silicide.

20. The structure of claim 19 wherein the underlying emitter silicon region comprises a first conductivity type and wherein an adjacent silicon region of a second conductivity type is substantially contiguous with the underlying emitter silicon region.

21. The structure of claim 20 wherein the adjacent silicon region and the underlying emitter silicon region are not substantially isolated from each other by a dielectric material.

22. The structure of claim 19 wherein the silicide comprises at least one of nickel and titanium.

23. The structure of claim 19 wherein the underlying silicon region comprises an amorphizing species, wherein the amorphizing species is substantially confined to an area beneath the silicide.

24. The structure of claim 19 wherein the amorphizing species comprises at least one of germanium, silicon combinations thereof.

25. The structure of claim 19 wherein the emitter contact comprises a p-type silicon material.

26. The structure of claim 19 wherein a base region adjacent to the emitter contact comprises an n-type silicon material.

27. The structure of claim 19 further comprising wherein the vertical bipolar transistor is disposed within a substrate, wherein the substrate further comprises a CMOS transistor.

28. The structure of claim 19 further comprising a system comprising:
a bus communicatively coupled to the vertical bipolar transistor; and
a DRAM communicatively coupled to the bus.

29. The structure of claim 28 wherein the vertical bipolar transistor is disposed within a substrate, wherein the substrate further comprises a CMOS transistor.
